(19) United States
(12) Patent Application Publication
(10) Pub. No.: US 2016/0233104 A1
(43) Pub. Date: Aug. 11, 2016

(54) METHODS OF FABRICATING SEMICONDUCTOR DEVICES USING SELF-ALIGNED SPACERS TO PROVIDE FINE PATTERNS

(71) Applicant: Samsung Electronics Co., Ltd., Suwon-si (KR)

(72) Inventors: NAM-GUN KIM, YONGIN-SI (KR); JINYOUNG KIM, HWASEONG-SI (KR); JONGCHEON KIM, SEOUL (KR); CHANMl LEE, SUWON-SI (KR); SUNGGIL CHOI, YONGIN-SI (KR); HYUN-CHUL YOON, SEONGNAM-SI (KR)

(21) Appl. No.: 14/976,296

(22) Filed: Dec. 21, 2015

(30) Foreign Application Priority Data
Feb. 9, 2015 (KR) 10-2015-0019498

(51) Int. Cl. H01L 21/308; H01L 21/3105; H01L 21/321; H01L 21/027; H01L 21/3065; H01L 21/3213

(52) U.S. Cl. CPC H01L 21/3086; H01L 21/3065; H01L 21/3081; H01L 21/32136; H01L 21/32139; H01L 21/32115; H01L 21/0273; H01L 21/31051

(57) ABSTRACT

A method of forming a semiconductor pattern can include providing an etching target layer. A hard mask pattern can be formed on the etching target layer using photolithography. First spacers can be formed on opposing sidewalls of the hard mask pattern and the hard mask pattern can be removed from between the first spacers to provide a first double patterning pattern self-aligned to the hard mask pattern. The planarization of top surfaces of the first double patterning pattern can be increased to provide a smoothed first double patterning pattern.

### CROSS-REFERENCE TO RELATED APPLICATION

This application claims priority under 35 U.S.C. §119 to Korean Patent Application No. 10-2015-0019498 filed on Feb. 9, 2015, the disclosure of which is hereby incorporated by reference in its entirety.

### FIELD

Embodiments of the inventive concept relate to methods of fabricating semiconductor devices for forming fine patterns thereof.

### BACKGROUND

With the trend of an increasing degree of integration in the semiconductor devices, patterns of the semiconductor devices have been further miniaturized.

Since the photolithography process margin has limitations, it is difficult for the fine patterns to be patterned by performing a single photolithography process.

Therefore, various techniques for improving the photolithography process margin have been proposed.

For example, multiple patterning technology process has been proposed to form fine patterns. However, a plurality of processes are added and thus there are problems in that process yields are reduced.

### SUMMARY

In accordance with an aspect of the inventive concept, a method of forming a semiconductor pattern can include providing an etching target layer. A hard mask pattern can be formed on the etching target layer using photolithography. First spacers can be formed on opposing sidewalls of the hard mask pattern and the hard mask pattern can be removed from between the first spacers to provide a first double patterning pattern self-aligned to the hard mask pattern. The planarization of top surfaces of the first double patterning pattern can be increased to provide a smoothed first double patterning pattern.

In some embodiments, a method of fabricating a semiconductor device includes providing an etching target layer and forming a hard mask pattern on the etching target layer. First spacers can be formed on opposing sidewalls of the hard mask pattern. The hard mask pattern can be removed and the first spacers maintained on the etching target layer. The planarization of top surfaces of the first spacers can be increased and second spacers can be formed on opposing sidewalls of the first spacers.

In some embodiments, a method of fabricating a semiconductor device includes providing an etching target layer and forming a first hard mask pattern and a second hard mask pattern sequentially stacked on the etching target layer. First spacers can be formed on sidewalls of the first and second hard mask patterns. An auxiliary hard mask material layer can be formed to fill a space between the first spacers and to cover the second hard mask pattern. An upper part of the auxiliary hard mask material layer and the second hard mask pattern can be removed and an auxiliary hard mask pattern can be formed between the first spacers. Upper surfaces of the first spacers, the first hard mask pattern, and the auxiliary hard mask pattern can be planarized and the first and auxiliary hard mask patterns can be removed. Second spacers can be formed on side surfaces of the first spacers.

In accordance with still another aspect of the inventive concept, a method of fabricating a semiconductor device includes sequentially forming a first hard mask material stack and a hard mask pattern on a substrate including a cell area and a peripheral area, forming first spacers on both side surfaces of the hard mask pattern in the cell area, removing the hard mask pattern, smoothing an upper end of the first spacer, forming second spacers on side surfaces of the first spacers, forming first hard mask pattern stacks by selectively etching the first hard mask material stack using the second spacers as etch masks, forming second hard mask pattern stacks on the first hard mask pattern stacks, forming the first hard mask pattern stacks by partly etching the first hard mask pattern stacks using the second hard mask pattern stacks as etch masks so as to have island shapes, and forming cell active patterns by etching the substrate using the first hard mask pattern stacks having the island shapes as etch masks.

In an embodiment, the hard mask material stack may include an oxide layer, an amorphous carbon layer (ACL), and a silicon oxynitride layer, which are sequentially stacked on the substrate. The cell active pattern may be formed to have an island shape. The forming of the second hard mask pattern stacks may include forming a second hard mask material stack which covers the first hard mask pattern stacks, forming a first photoresist pattern on the second hard mask material stack so as to have through holes partly corresponding to the first hard mask pattern stacks, etching the second hard mask material stack corresponding to the through holes and some of the first hard mask pattern stacks using the first photoresist pattern as an etch mask, and removing the first photoresist pattern and the second hard mask material stack.

In another embodiment, the method may include forming the second hard mask material stack on the first hard mask material stack in the peripheral area, forming a second photoresist pattern having an island shape on the second hard mask material stack, forming a peripheral hard mask pattern stack by etching the first hard mask material stack and the second hard mask material stack using the second photoresist pattern as an etch mask, removing the second photoresist pattern and the second hard mask material stack, and forming a peripheral active pattern by etching the substrate using the peripheral hard mask pattern stack as an etch mask.

### BRIEF DESCRIPTION OF THE DRAWINGS

FIGS. 1 to 11 are cross-sectional views showing a method of fabricating a semiconductor device in accordance with embodiments of the inventive concept;

FIGS. 12 to 14 are cross-sectional views showing a method of fabricating a semiconductor device in accordance with embodiments of the inventive concept;

FIG. 15A is a plan view showing a configuration of active patterns formed in a cell area (CA) and a peripheral area (PA) of a semiconductor device according to embodiments of the inventive concept, and FIG. 15B shows a cross-sectional view of a CA taken along line I-I′ of FIG. 15A and a cross-sectional view of a PA taken along line II-II′ of FIG. 15A;

FIGS. 16, 31, and 34 are plan views illustrating methods of fabricating semiconductor devices according to embodiments of the inventive concept shown in FIGS. 15A and 15B;

FIGS. 17 to 30, 32 and 33, and 35 to 37 are cross-sectional views showing methods of fabricating the semiconductor devices according to embodiments of the inventive concept and corresponding to lines I-I′ and II-II′ of FIG. 15A;

FIG. 17 is a cross-sectional view taken along lines I-I′ and II-II′ of FIG. 16;

FIG. 32 is a cross-sectional view taken along lines I-I′ and II-II′ of FIG. 31;

FIG. 35 is a cross-sectional view taken along lines I-I′ and II-II′ of FIG. 34;

FIGS. 38 to 40 are cross-sectional views illustrating a method of fabricating a semiconductor device in according to embodiments of the inventive concept and corresponding to lines I-I′ and II-II′ of FIG. 15A;

FIG. 41 illustrates a semiconductor module in accordance with embodiments of the inventive concept; and

FIG. 42 is a block diagram showing an electronic system in accordance with embodiments of the inventive concept.

### DETAILED DESCRIPTION OF THE EMBODIMENTS

Advantages and features of the inventive concept and methods of accomplishing them will be made apparent with reference to the accompanying drawings and some embodiments to be described below. The inventive concept may, however, be embodied in various different forms, and should be construed as limited, not by the embodiments set forth herein, but only by the accompanying claims. Rather, these embodiments are provided so that this disclosure is thorough and complete and fully conveys the inventive concept to those skilled in the art.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to,” or “directly coupled to” another element or layer, there are no intervening elements or layers present. Like reference numerals throughout this specification denote like elements. As used herein, the term “and/or” includes any and all combinations of one or more of the associated listed items.

Spatially relative terms, such as “below,” “beneath,” “lower,” “above,” “upper,” and the like, may be used herein for ease of description in describing one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein may be interpreted accordingly.

The exemplary embodiments of the invention will be described with reference to cross-sectional views and/or plan views, which are ideal exemplary views. Thicknesses of layers and areas are exaggerated for effective description of the technical contents in the drawings. Forms of the embodiments may be modified by the manufacturing technology and/or tolerance. Therefore, the embodiments of the invention are not intended to be limited to illustrated specific forms, and include modifications of forms generated according to manufacturing processes. For example, an etching area illustrated at a right angle may be round or have a predetermined curvature. Therefore, areas illustrated in the drawings have overview properties, and shapes of the areas are illustrated special forms of the areas of a device, and are not intended to be limited to the scope of the invention.

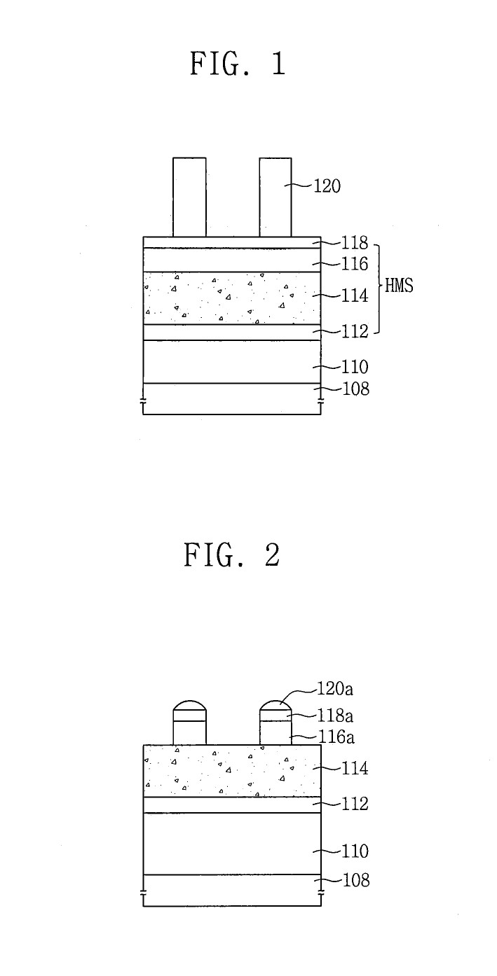

FIGS. 1 to 11 are cross-sectional views showing a method of fabricating a semiconductor device in accordance with embodiments of the inventive concept.

Referring to FIG. 1, the method of fabricating the semiconductor device in accordance with embodiments of the inventive concept may include providing an etching target layer 110 on a substrate 108, stacking a hard mask material stack HMS on the etching target layer 110, and forming photo resist (PR) patterns 120 on the hard mask material stack HMS. The PR patterns 120 may be photoresist patterns.

The substrate 108 may be a semiconductor substrate. For example, the substrate 108 may be a silicon substrate or a silicon on insulator (SOI) substrate.

The etching target layer 110 may include polysilicon or a metal material. In some embodiments of the inventive concept, the etching target layer 110 may be a part of the substrate 108.

The hard mask material stack HMS may include a first hard mask material layer 112, a second hard mask material layer 114, a third hard mask material layer 116, and a fourth hard mask material layer 118.

The first hard mask material layer 112 and the third hard mask material layer 116 may include silicon oxynitride (SiON). The second hard mask material layer 114 may include a spin on hard mask (SOH). The fourth hard mask material layer 118 may include a bottom anti-reflective coating (BARC). The BARC may be a compound containing silicon. The BARC may prevent a configuration of the PR patterns 120 from being damaged by a reflection of light that is irradiated in order to pattern the PR patterns 120.

The hard mask material stack HMS may be used to transfer the PR patterns 120 to the etching target layer 110. For example, in implementing fine patterns having a thickness of 70 nm or less, when a conventional PR is used, an aspect ratio thereof may be increased, and thus the PR patterns 120 may collapse. When thicknesses of the PR patterns 120 are reduced in order to solve the above-described problem, the patterns may not be formed to have depths to be desired. Therefore, another hard mask pattern stack may be further formed under the PR instead of reducing a thickness of the PR.

Referring to FIG. 2, the method may include forming third hard mask patterns 116a and fourth hard mask patterns 118a.

The forming of the third hard mask patterns 116a and the fourth hard mask patterns 118a may include selectively etching the fourth hard mask material layer 118 exposed by the PR patterns 120, and the third hard mask material layer 116 formed thereunder using the PR patterns 120 as etch masks. The etching of the third hard mask material layer 116 and the fourth hard mask material layer 118 may include a dry etching method. While the etching process is performed, parts of the PR patterns 120 may be removed. Remaining PR patterns 120a may remain on the fourth hard mask patterns 118a after the etching process.

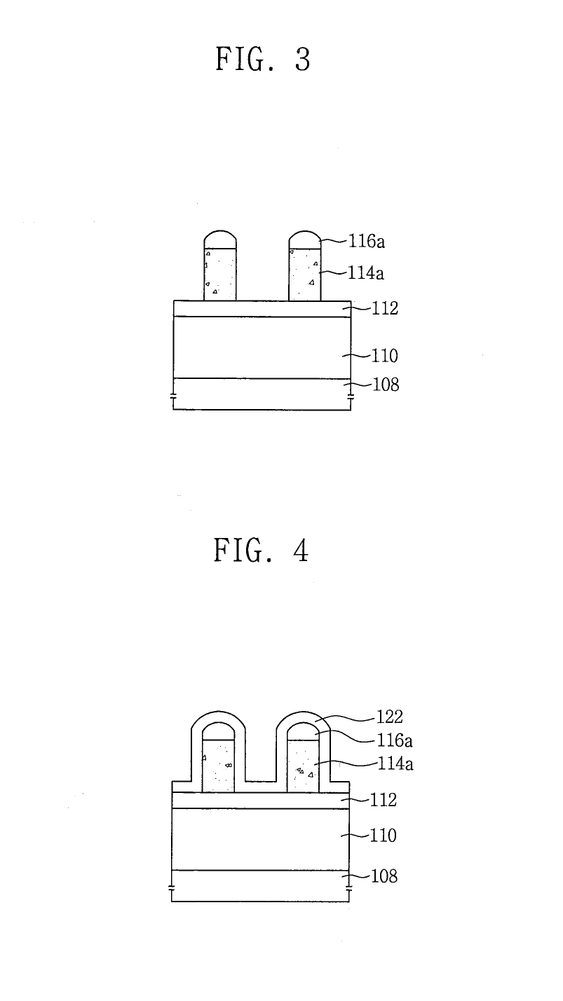

Referring to FIG. 3, the method may include forming second hard mask patterns 114a, and removing the remaining PR patterns 120a and the fourth hard mask patterns 118a. Parts of the third hard mask patterns 116a may remain on the second hard mask patterns 114a.

The forming of the second hard mask patterns 114a may include selectively removing the second hard mask material layer 114 exposed by the third hard mask patterns 116a using the remaining PR patterns 120a, the fourth hard mask patterns 118a, and the third hard mask patterns 116a as etch masks.

Referring to FIG. 4, the method may include forming a first spacer material layer 122.

The first spacer material layer 122 may be conformally formed on an upper surface of the first hard mask material layer 112 exposed by the second hard mask patterns 114a, and surfaces of the second and third hard mask patterns 114a and 116a.

The first spacer material layer 122 may include polysilicon. For example, the first spacer material layer 122 may be formed by performing an atomic layer deposition (ALD) process.

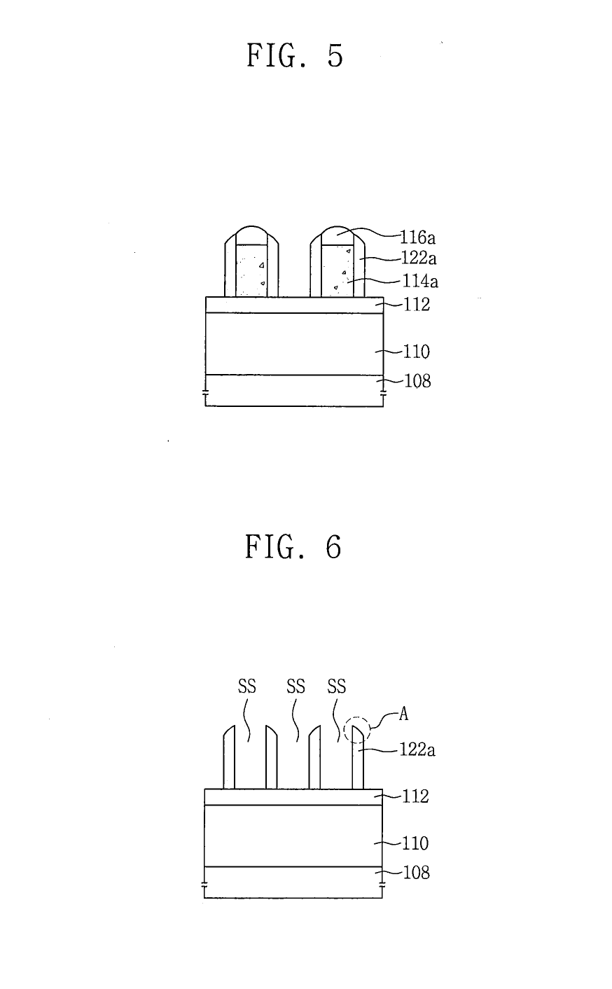

Referring to FIG. 5, the method may include forming first spacers 122a by partially etching the first spacer material layer 122.

The first spacers 122a may be formed on side surfaces of the second hard mask patterns 114a and the third hard mask patterns 116a.

The forming of the first spacers 122a may include removing the first spacer material layer 122 formed on the upper surface of the first hard mask material layer 112 and upper surfaces of the third hard mask patterns 116a. For example, the forming of the first spacers 122a may include performing an anisotropic etching process on the first spacer material layer 122 to expose the upper surfaces of the third hard mask patterns 116a.

Referring to FIG. 6, the method may include removing the second hard mask patterns 114a and the third hard mask patterns 116a, and leaving the first spacers 122a.

Separated spaces SS may be formed between the first spacers 122a by removing the second hard mask patterns 114a and the third hard mask patterns 116a. A portion of the first hard mask material layer 112 may be exposed by the separated spaces SS. Each of the first spacers 122a may have an upper end A having a rounded shape. The upper ends A of the first spacers 122a may be non-uniformly distributed on the substrate 108 in rounded shapes.

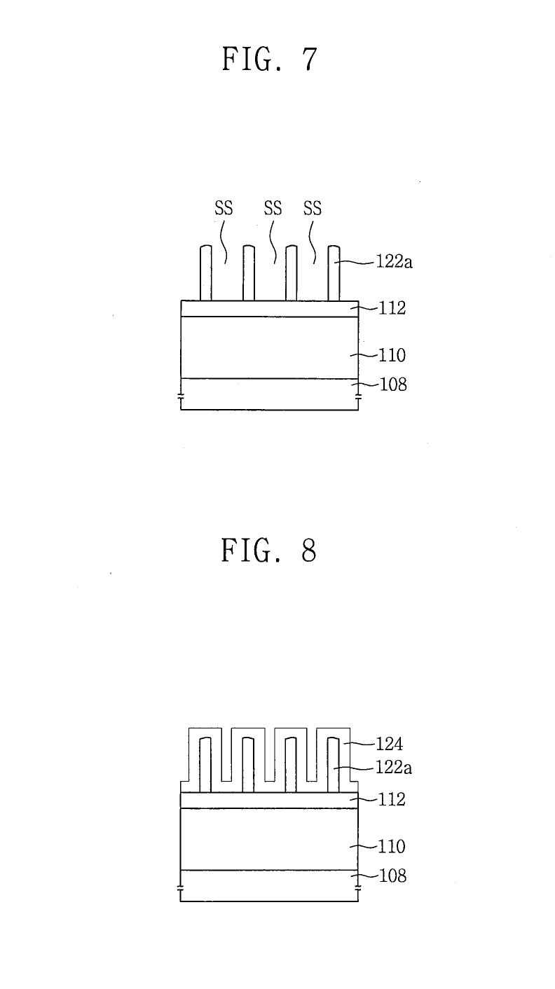

Referring to FIG. 7, the method may include performing a smoothing process on the upper ends A of the first spacers 122a. The smoothing process may include a plasma etching process. An etching gas used in the smoothing process may include Cl₂, HBr, O₂, SiCl₄, and/or SiBr. The smoothing process (e.g., a plasma etching process) may be performed in a chamber to which a high voltage bias is applied. As the non-uniformly distributed upper ends A of the first spacers 122a having rounded shapes are removed through the smoothing process, the first spacers 122a may have a more uniform distribution characteristic compared to that shown in FIG. 6. Therefore, the distribution characteristic of widths and heights of the first spacers 122a can be improved relative to FIG. 6.

Therefore, two patterns (a pair of the first spacers 122a) may be formed from one pattern (one of the PR patterns 120).

Referring to FIG. 8, the method may include forming a second spacer material layer 124.

The second spacer material layer 124 may be conformally formed on the upper surface of the first hard mask material layer 112 exposed by the first spacers 122a (e.g., the separated space SS), and surfaces of the first spacer 122a.

The second spacer material layer 124 may include silicon oxide. The second spacer material layer 124 may be formed by performing an ALD process.

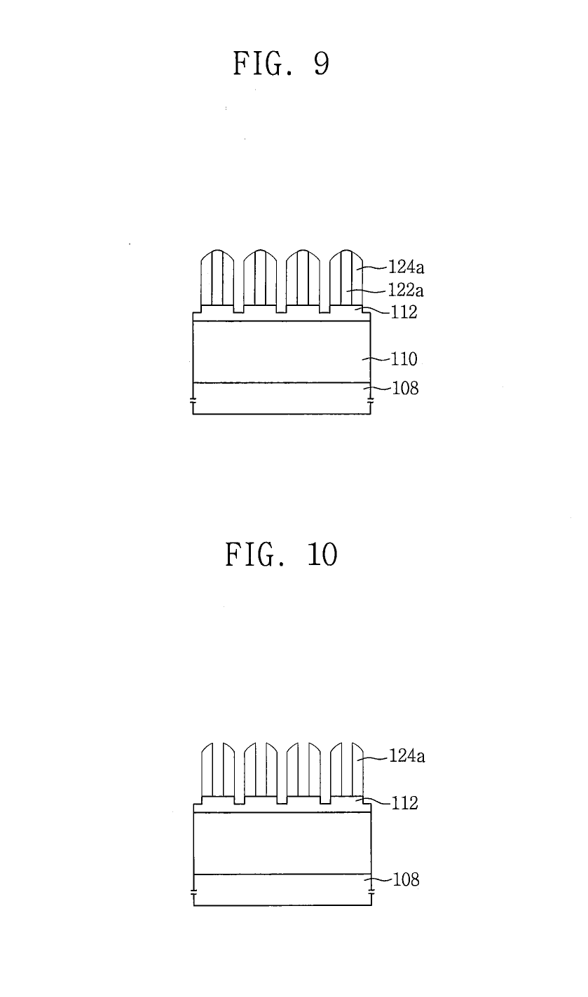

Referring to FIG. 9, the method may include forming second spacers 124a.

The forming of the second spacers 124a may include selectively removing the second spacer material layer 124 formed on the upper surface of the first hard mask material layer 112 and on the first spacers 122a. For example, the second spacers 124a may be formed by performing an anisotropic etching process on the second spacer material layer 124 so that upper surfaces of the first spacers 122a are exposed. During the anisotropic etching process the upper surface of the first hard mask material layer 112 exposed by the second spacers 124a may be recessed.

Referring to FIG. 10, the method may include removing the first spacers 122a.

As the first spacers 122a are removed, only the second spacers 124a may remain on the first hard mask material layer 112. Therefore, according to embodiments of the inventive concept, four patterns (two pairs of the second spacers 124a) may be formed from one pattern (one of the PR patterns 120). In some embodiments of the inventive concept, a smoothing process may be performed on upper ends of the second spacers 124a. For example, in order to remove rounded shapes of the upper ends of the second spacers 124a, the smoothing process described with reference to FIG. 7 may be applied.

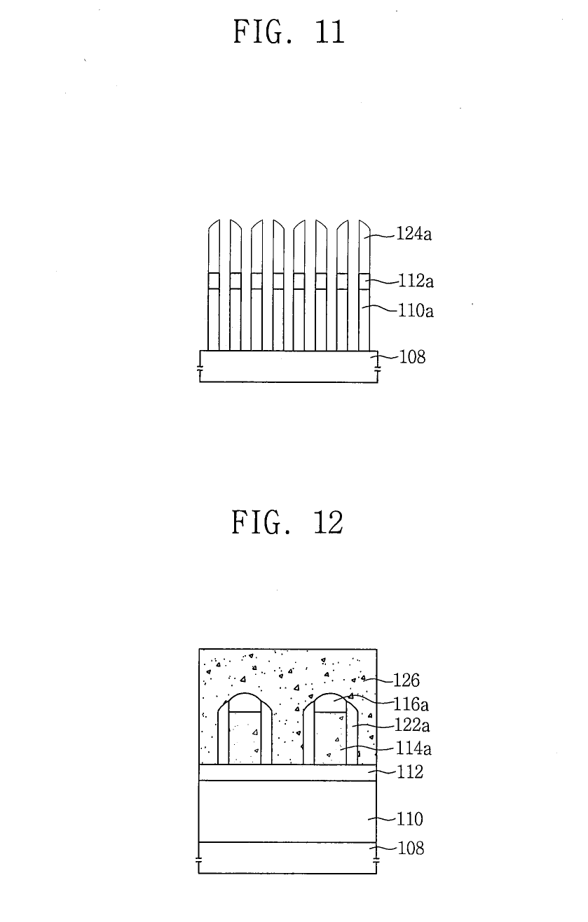

Referring to FIG. 11, the method may include forming first hard mask patterns 112a and a plurality of target patterns 110a.

The forming of the first hard mask patterns 112a may include removing the first hard mask material layer 112 exposed between the second spacers 124a. The forming of the target patterns 110a may include selectively etching the etching target layer 110 using the first hard mask patterns 112a as etch masks.

Therefore, the patterns of the semiconductor device may be formed through a quadruple patterning technology (QPT) in accordance with embodiments of the inventive concept.

Hereinafter, a method of fabricating a semiconductor device in accordance with embodiments of the inventive concept will be described with reference to views FIGS. 12 to 14.

FIGS. 12 to 14 are cross-sectional views showing a method of fabricating the semiconductor device in accordance with embodiments of the inventive concept.

Hereinafter, since processes which are performed before a process of FIG. 12 are the same as those described with reference to FIGS. 1 to 5, the processes may be briefly described.

Referring to FIG. 12, the method of fabricating the semiconductor device in accordance with embodiments of the inventive concept may include forming an etching target layer 110 on a substrate 108, forming a first hard mask material layer 112 on the etching target layer 110, forming second hard mask patterns 114a and third hard mask patterns 116a on the first hard mask material layer 112, forming first spacers 122a on side surfaces of the second and third hard mask patterns 114a and 116a, and forming an auxiliary hard mask material layer 126 which fills spaces between the first spacers 122a and covers the first spacers 122a and the third hard mask patterns 116a. The structure shown in FIG. 12 may be provided by the approach shown in FIGS. 1-5 with the formation of the auxiliary hard mask material layer 126.

The first hard mask material layer 112 may include silicon oxynitride (SiON). The second hard mask pattern 114a may include an SOH. The third hard mask pattern 116a may include silicon oxynitride (SiON). The auxiliary hard mask material layer 126 may include an SOH layer. Each of the first spacers 122a may include polysilicon.

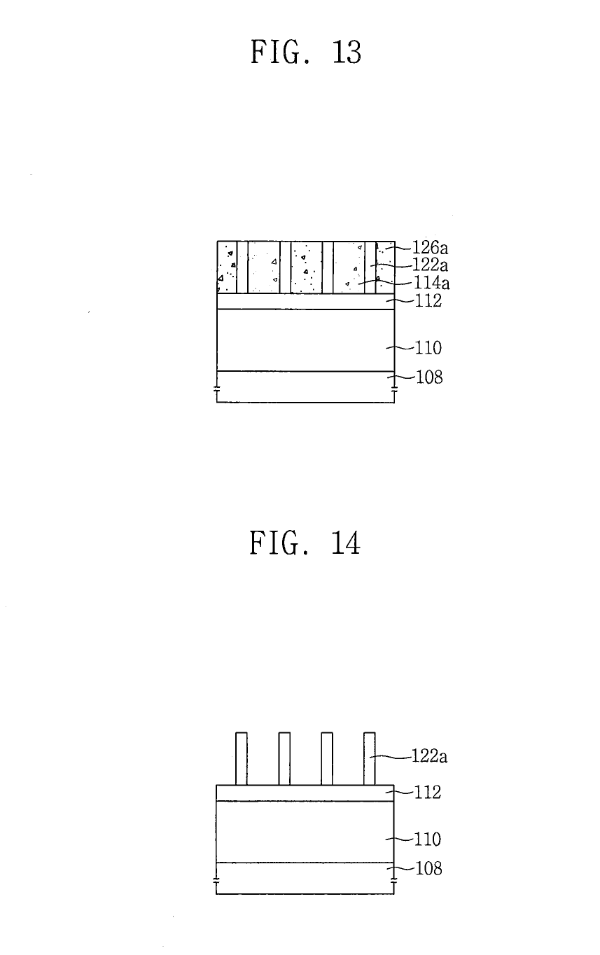

Referring to FIG. 13, the method may include forming auxiliary hard mask patterns 126a.

The forming of the auxiliary hard mask patterns 126a may include a planarization process. Through the planarization process, a part of the auxiliary hard mask material layer 126 and the third hard mask patterns 116a may be removed. Through the planarization process, upper parts of the second hard mask patterns 114a and upper parts of the first spacers 122a may be partially removed. Through the planarization process, upper surfaces of the first spacers 122a, the second hard mask patterns 114a, and the auxiliary hard mask patterns 126a may be planarized. The planarization process may include an etch-back process or a chemical mechanical planarization (CMP) process. Accordingly, in some embodiments, smoothing of the first spacers 122a can be carried out by a planarization process.

Referring to FIG. 14, the method may include removing the second hard mask patterns 114a exposed by the first spacers 122a, and the auxiliary hard mask patterns 126a, to leave the first spacers 122a on the first hard mask material layer 112.

Then, the method may include forming target patterns 110a by performing the processes described with reference to FIGS. 8 to 11.

The above-described processes may be applied to processes of forming active patterns and conductive patterns of the semiconductor device.

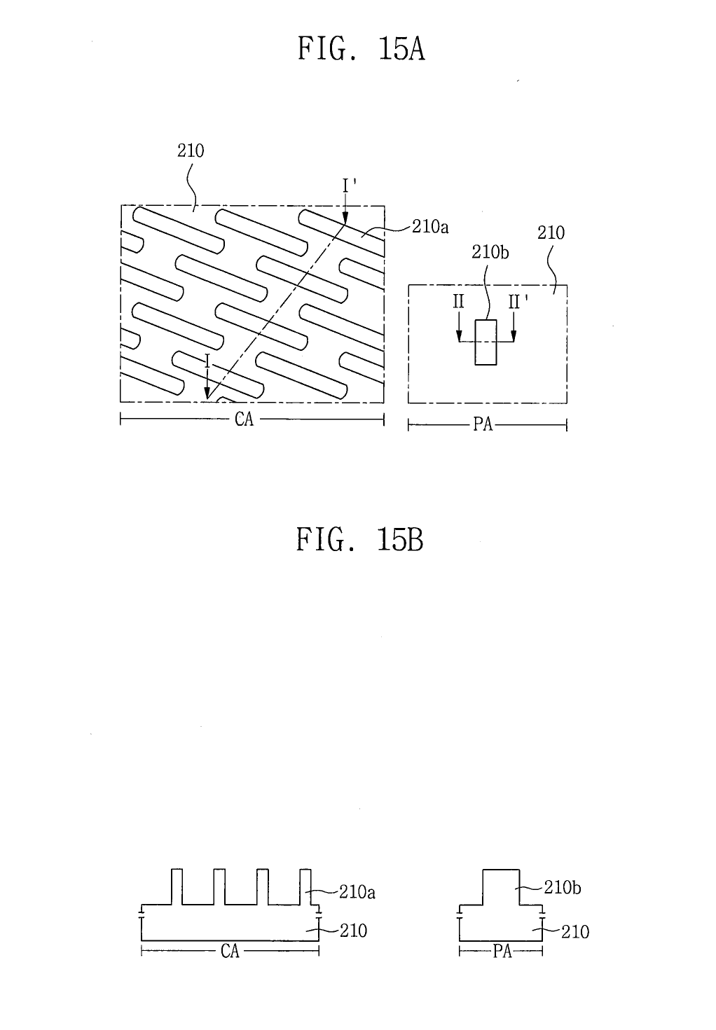

FIG. 15A is a plan view showing a configuration of active patterns formed in a cell area (CA) and a peripheral area (PA) of a semiconductor device according to embodiments of the inventive concept, and FIG. 15B shows cross-sectional views taken along lines I-I′ and II-II′ of FIG. 15A.

Referring to FIGS. 15A and 15B, the semiconductor device in accordance with embodiments of the inventive concept may include cell active patterns 210a and a peripheral active pattern 210b formed in the cell area CA and the peripheral area PA, respectively.

Each of the cell active patterns 210a may be bar shaped. The cell active patterns 210a may have a predetermined orientation, and may be spaced a predetermined distance from each other.

Hereinafter, a process of forming active patterns of the semiconductor device to which a process of forming fine patterns according to embodiments of the inventive concept is applied will be described with reference to views of a process.

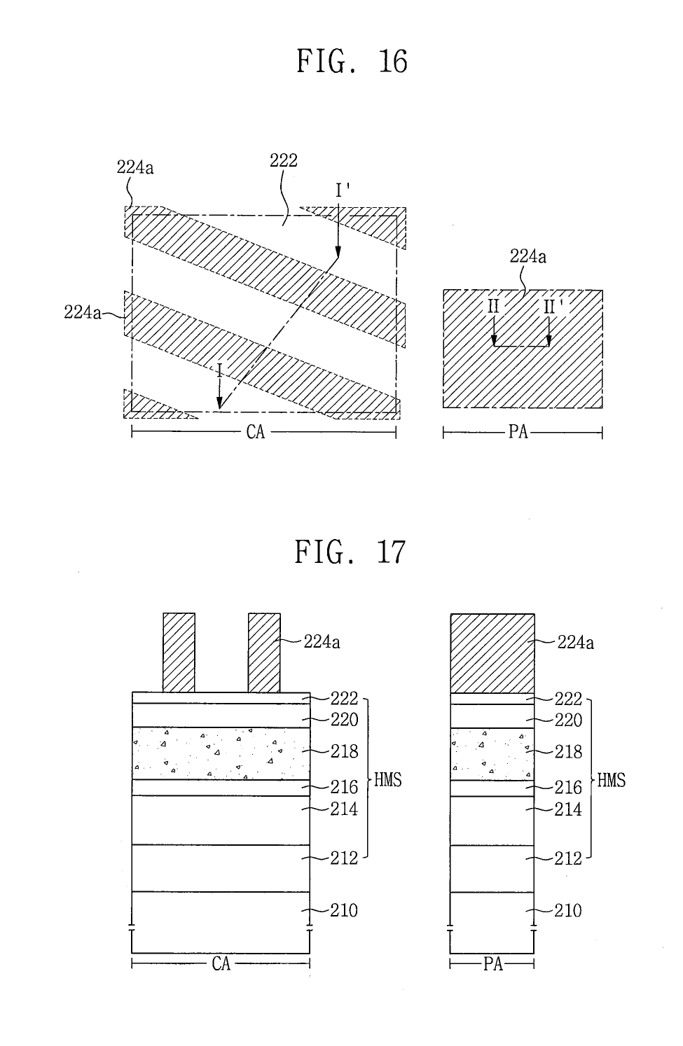

FIGS. 16, 31, and 34 are plan views illustrating methods of fabricating semiconductor devices according to embodiments of the inventive concept shown in FIGS. 15A and 15B.

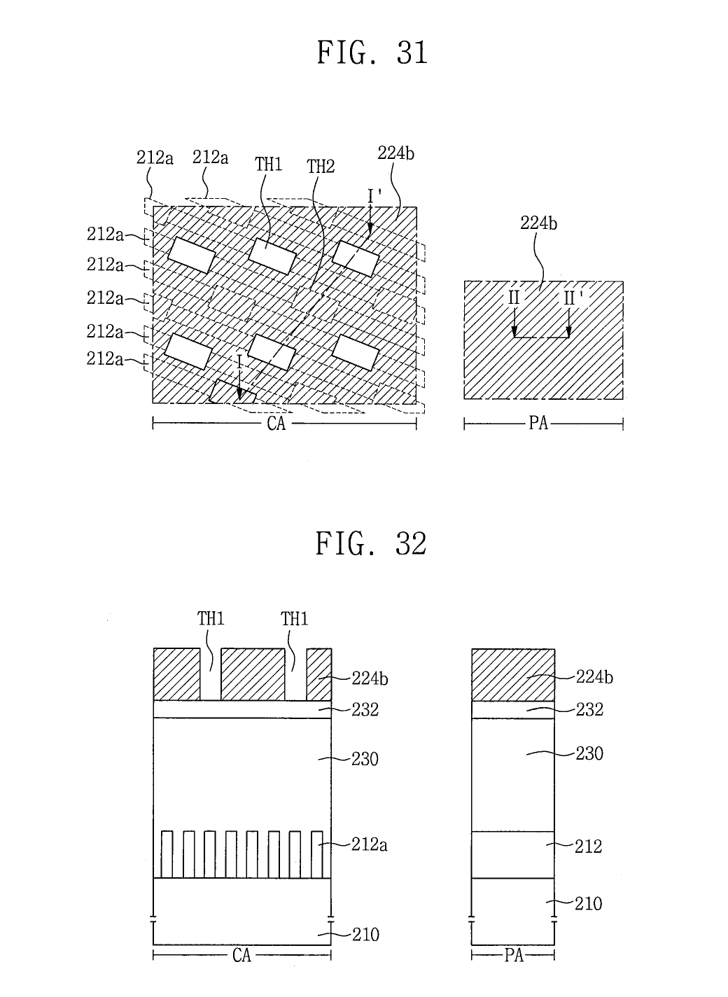

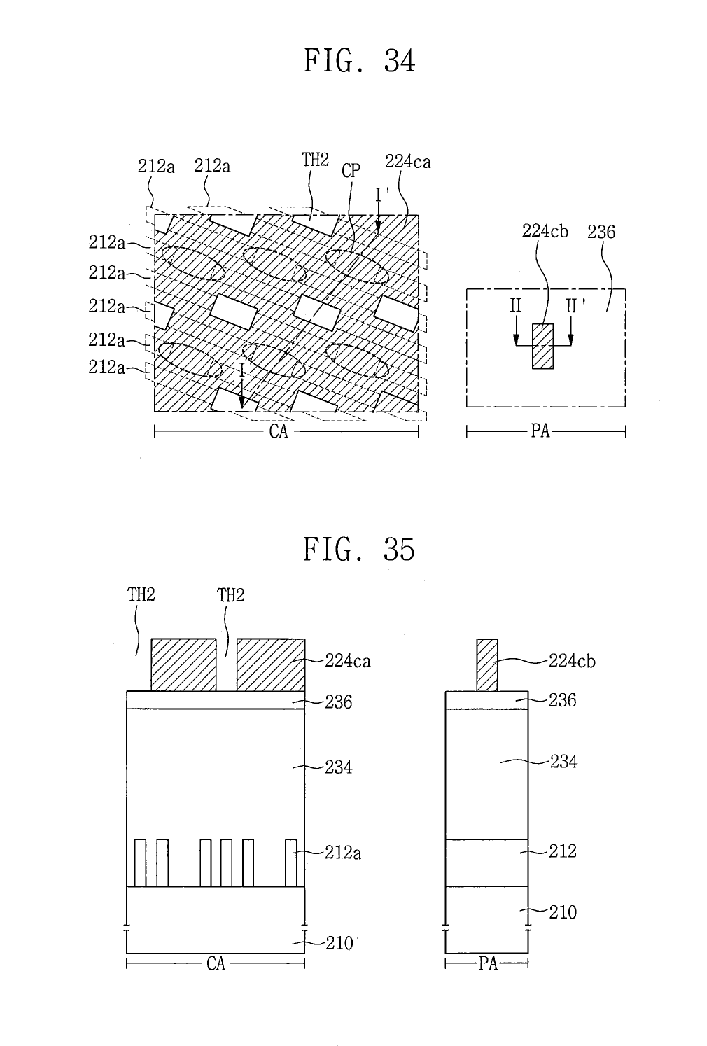

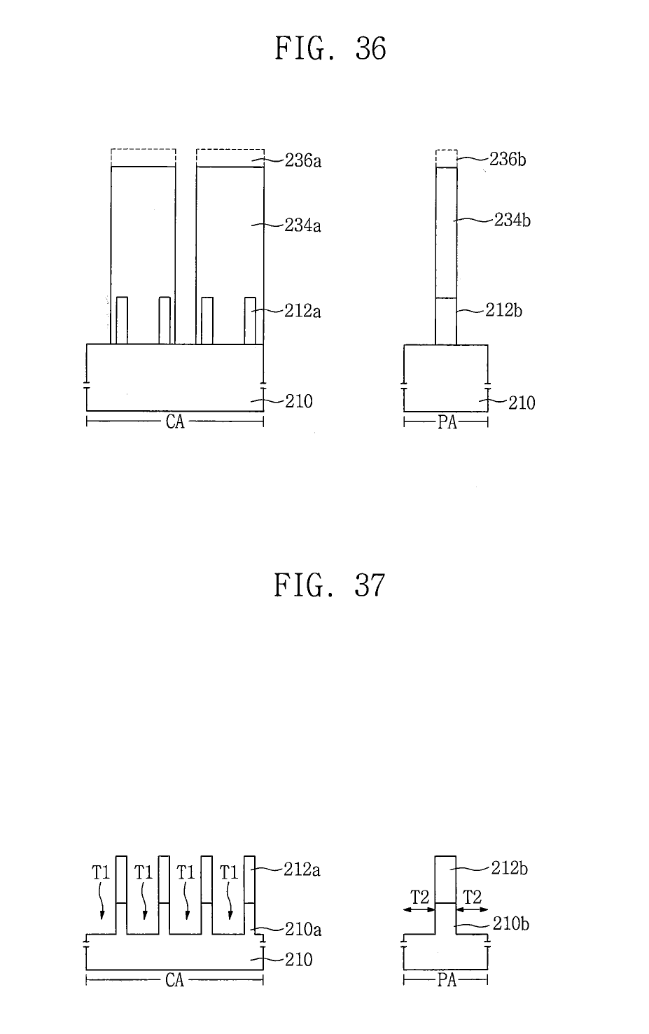

FIGS. 17 to 30, 32 and 33, and 35 to 37 are cross-sectional views of methods of fabricating the semiconductor devices according to embodiments of the inventive concept. Each of the cross-sectional views corresponds to a cross-sectional view taken along lines I-I′ and II-II′ of FIG. 15. FIG. 17 is a cross-sectional view taken along lines I-I′ and II-II′ of FIG. 16. FIG. 32 is a cross-sectional view taken along lines I-I′ and II-II′ of FIG. 31. FIG. 35 is a cross-sectional view taken along lines I-I′ and II-II′ of FIG. 34.

Referring to FIGS. 16 and 17, the method of fabricating the semiconductor device according to embodiments of the inventive concept may include forming a hard mask material stack HMS on a substrate 210 and forming first PR patterns 224a on the hard mask material stack HMS. The first PR patterns 224a may be photoresist patterns.

The substrate 210 may include the cell area CA and the peripheral area PA. The hard mask material stack HMS may include a first hard mask material layer 212, a second hard mask material layer 214, a third hard mask material layer 216, a fourth hard mask material layer 218, a fifth hard mask material layer 220, and a sixth hard mask material layer 222. The first PR patterns 224a may be formed through a photolithography process.

In a plan view, the first PR patterns 224a may be formed to be stripe shaped in the cell area CA and may cover the peripheral area PA. The first PR patterns 224a of the cell area CA may have the same orientation as the cell active patterns 210a of FIG. 15A.

The substrate 210 may include a silicon wafer. The first hard mask material layer 212 may include silicon oxide (SiOx). The second hard mask material layer 214 may include an amorphous carbon (A-C) layer. Each of the third hard mask material layer 216 and the fifth hard mask material layer 220 may include silicon oxynitride (SiON). The fourth hard mask material layer 218 may include an SOH layer. The sixth hard mask material layer 222 may be a BARC layer.

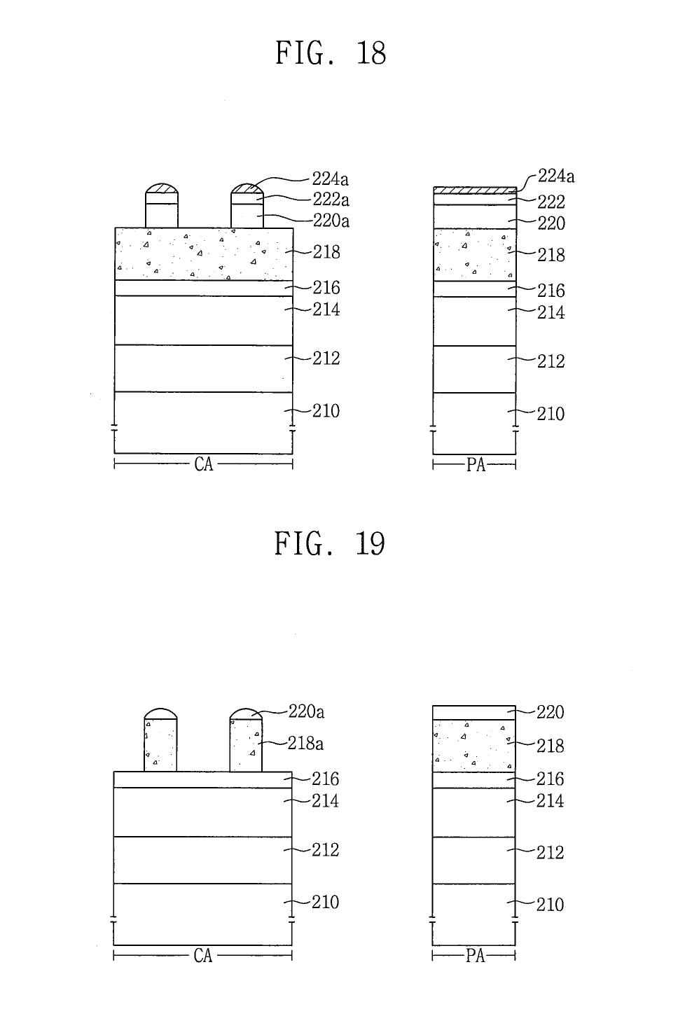

Referring to FIG. 18, the method may include forming fifth hard mask patterns 220a and sixth hard mask patterns 222a in the cell area CA.

The forming of the fifth hard mask patterns 220a and the sixth hard mask patterns 222a may include selectively etching the sixth hard mask material layer 222 exposed by the first PR patterns 224a, and the fifth hard mask material layer 220 formed thereunder using the first PR patterns 224a as etch masks.

For example, the fifth hard mask material layer 220 and the sixth hard mask material layer 222 may be etched by performing a dry etching process. While the etching process is performed, in the cell area CA, the first PR patterns 224a may be partially etched and may remain on the sixth hard mask patterns 222a. In the peripheral area PA, the first PR patterns 224a may be partially etched and the sixth hard mask material layer 222 may be protected from being etched by the first PR patterns 224a.

Referring to FIG. 19, the method may include forming fourth hard mask patterns 218a, and removing the remaining first PR patterns 224a, and the sixth hard mask patterns 222a and the sixth hard mask material layer 222 which are formed under the remaining first PR patterns 224a.

The forming of the fourth hard mask patterns 218a in the cell area CA may include selectively removing the fourth hard mask material layer 218 exposed by the fifth hard mask patterns 220a. In the peripheral area PA, the fourth hard mask material layer 218 may be protected by the fifth hard mask material layer 220, and the fifth hard mask material layer 220 may be partially etched.

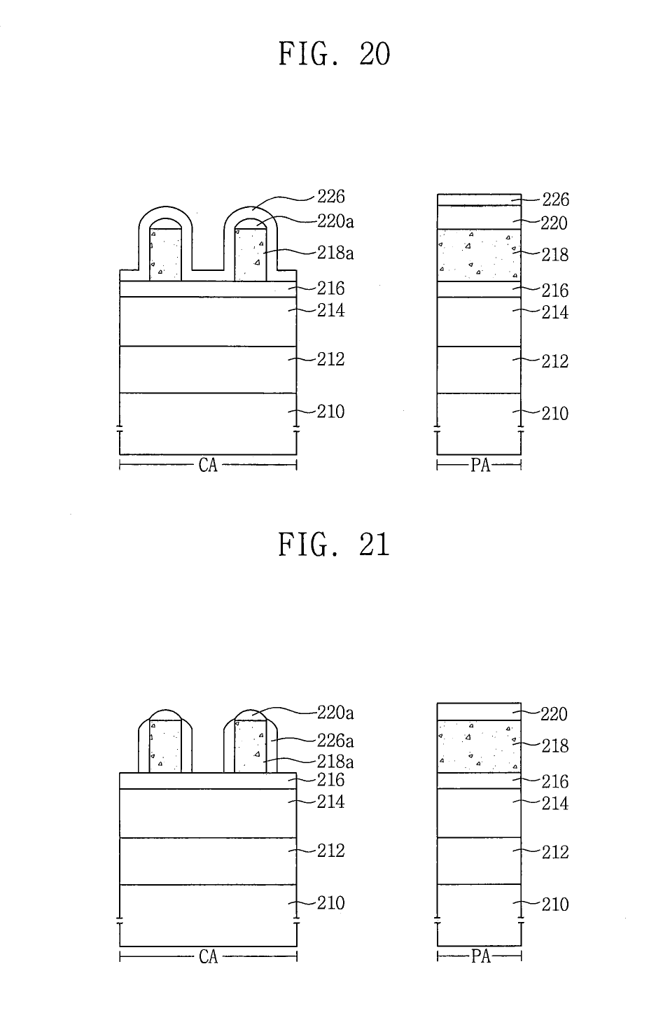

Referring to FIG. 20, the method may include forming a first spacer material layer 226.

In the cell area CA, the first spacer material layer 226 may be conformally formed along an upper surface of the third hard mask material layer 216 exposed by the fourth hard mask patterns 218a, side surfaces of the fourth hard mask patterns 218a and the fifth hard mask patterns 220a, and upper surfaces of the fifth hard mask patterns 220a. In the peripheral area PA, the first spacer material layer 226 may be formed on the fifth hard mask material layer 220.

The first spacer material layer 226 may include polysilicon. For example, the first spacer material layer 226 may be formed by performing an ALD process.

Referring to FIG. 21, the method may include forming first spacers 226a in the cell area CA.

The first spacers 226a may be formed on side surfaces of the fourth and fifth hard mask patterns 218a and 220a.

The forming of the first spacers 226a may include removing the first spacer material layer 226 formed on the upper surface of the third hard mask material layer 216 and the upper surfaces of the fifth hard mask patterns 220a. For example, the first spacers 226a may be formed by performing an anisotropic etching process on the first spacer material layer 226 so that the upper surfaces of the fifth hard mask patterns 220a are exposed. In the peripheral area PA, the first spacer material layer 226 may be removed and the fifth hard mask material layer 220 may be exposed.

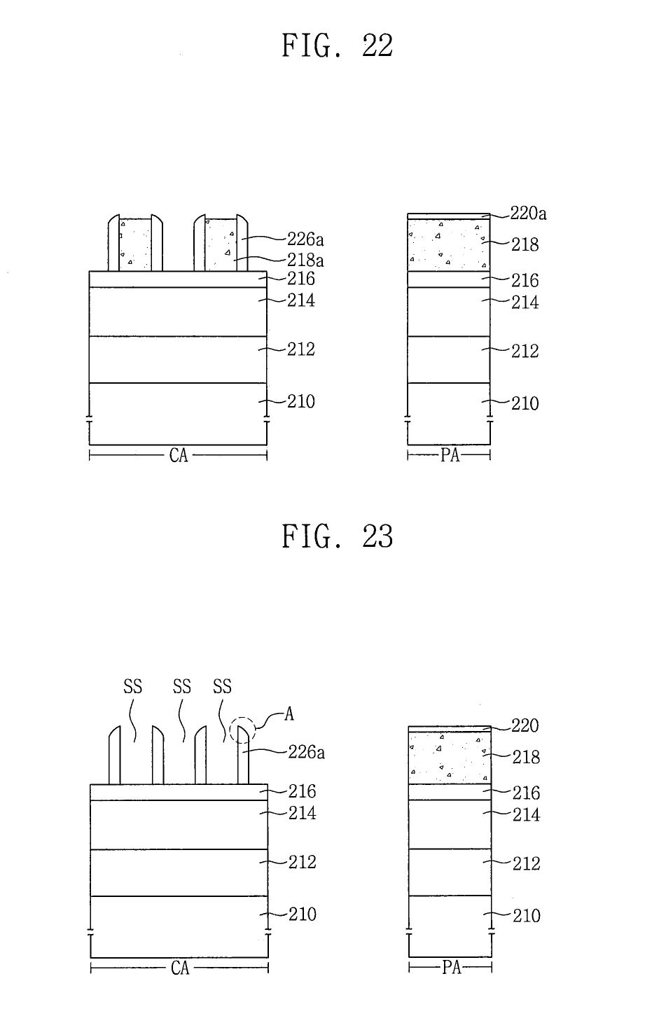

Referring to FIG. 22, the method may include removing the fifth hard mask patterns 220a.

When the fifth hard mask patterns 220a are removed, surfaces of the fourth hard mask patterns 218a of the cell area CA may be exposed. The fifth hard mask material layer 220 of the peripheral area PA may be simultaneously etched with the fifth hard mask patterns 220a. The fifth hard mask patterns 220a may thinly remain on an upper surface of the fourth hard mask material layer 218 in the peripheral area PA.

Referring to FIG. 23, the method may include removing the fourth hard mask patterns 218a.

As the fourth hard mask patterns 218a are removed, in the cell area CA, separated spaces SS may be present between the first spacers 226a, and the upper surface of the third hard mask material layer 216 may be exposed by the first spacers 226a. In the peripheral area PA, the fifth hard mask material layer 220 may remain. In this case, each of upper ends A of the first spacers 226a may have a rounded shape. The rounded shapes of the upper ends A of the first spacers 226a may be non-uniformly distributed across the cell area CA. In other words, one side of the upper end of the first spacers 226a may be higher than the other.

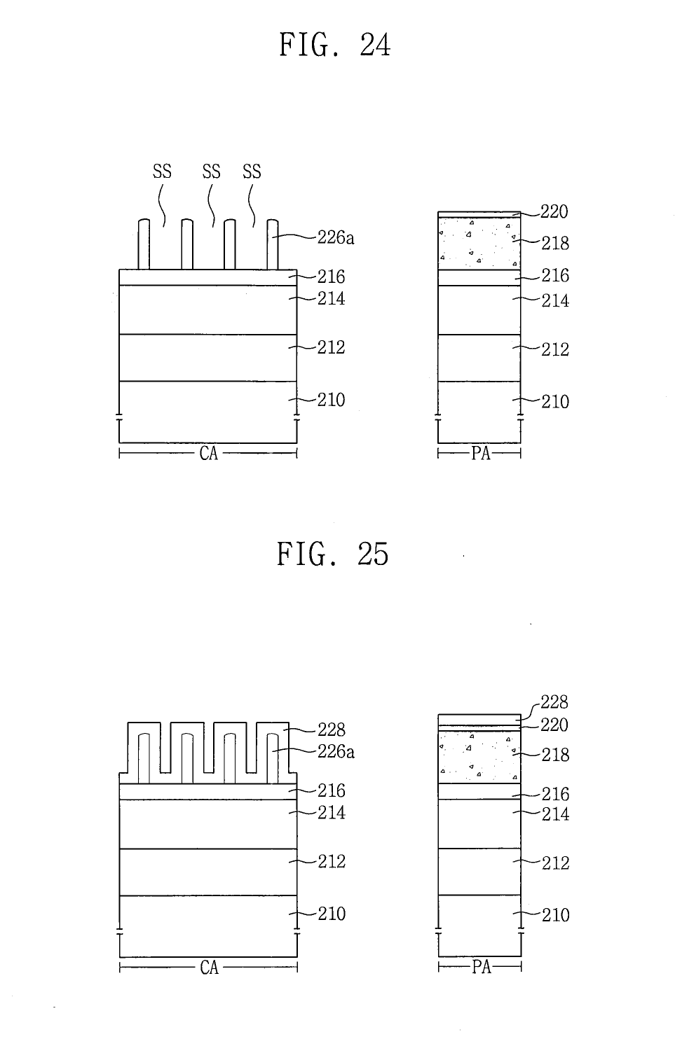

Referring to FIG. 24, the method may include performing a smoothing process in which the upper ends A of the first spacers 226a are removed.

The smoothing process may include a plasma etching process. In this case, an etching gas used in the smoothing process may include Cl₂, HBr, O₂, SiCl₄, and/or SiBr. The smoothing process may be performed in a chamber to which a high voltage is applied. Through the smoothing process, the first spacers 226a may have more uniform heights and/or widths.

As a result of performing the above-described processes, two patterns (a pair of the first spacers 226a) may be formed from one pattern (one of the first PR patterns 224a).

Referring to FIG. 25, the method may include forming a second spacer material layer 228.

In the cell area CA, the second spacer material layer 228 may be conformally formed along the upper surface of the third hard mask material layer 216 exposed by the first spacers 226a, for example, in the separated space SS, and the surfaces of the first spacers 226a. In the peripheral area PA, the second spacer material layer 228 may cover an upper surface of the fifth hard mask material layer 220.

The second spacer material layer 228 may include silicon oxide (SiOx). For example, the second spacer material layer 228 may be formed by performing an ALD process.

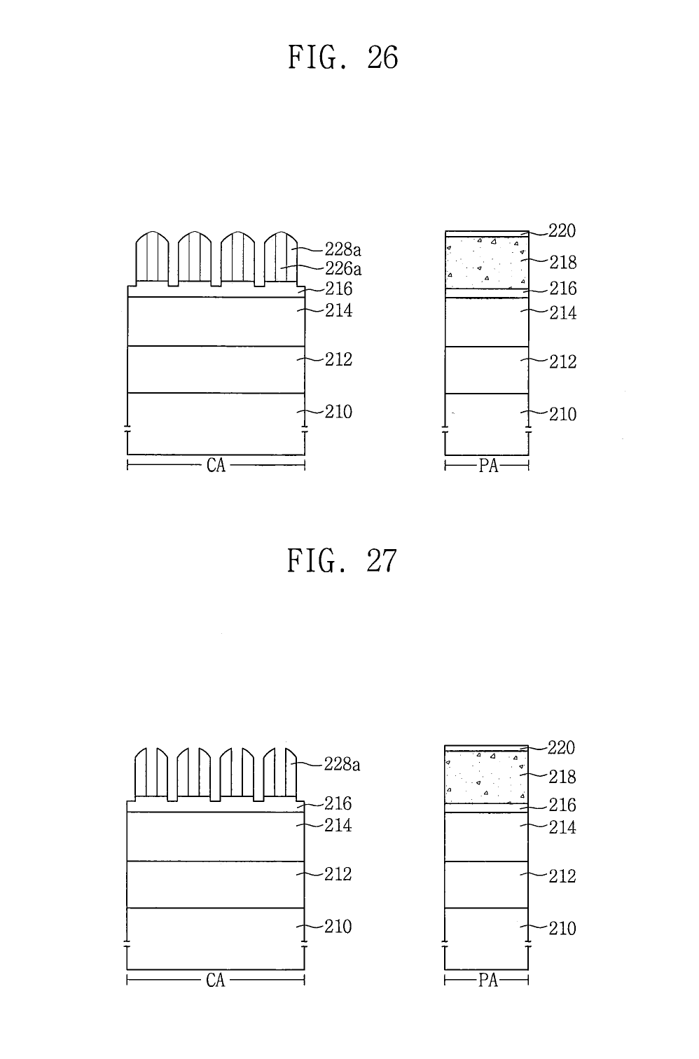

Referring to FIG. 26, the method may include forming second spacers 228a in the cell area CA.

The forming of the second spacers 228a may include removing the second spacer material layer 228 from the upper surface of the third hard mask material layer 216 and upper surfaces of the first spacers 226a. For example, the removing of the second spacer material layer 228 may include performing an anisotropic etching process. During the anisotropic etching process the upper surface of the third hard mask material layer 216 formed between the second spacers 228a may be recessed. In the peripheral area PA, the second spacer material layer 228 may be removed and the fifth hard mask material layer 220 may be exposed.

Referring to FIG. 27, the method may include removing the first spacers 226a in the cell area CA.

As the first spacers 226a are removed, in the cell area, only the second spacers 228a spaced apart from each other may be present on the third hard mask material layer 216 CA. Therefore, four patterns (two pairs of the second spacers 228a) may be formed from one pattern (one of the first PR patterns 224a (shown in FIG. 17)) through a single photolithography process. In some embodiments of the inventive concept, a smoothing process may be performed on upper ends of the second spacers 228a. For example, in order to remove rounded shapes of the upper ends of the second spacers 228a, the smoothing process described with reference to FIG. 24 may be applied.

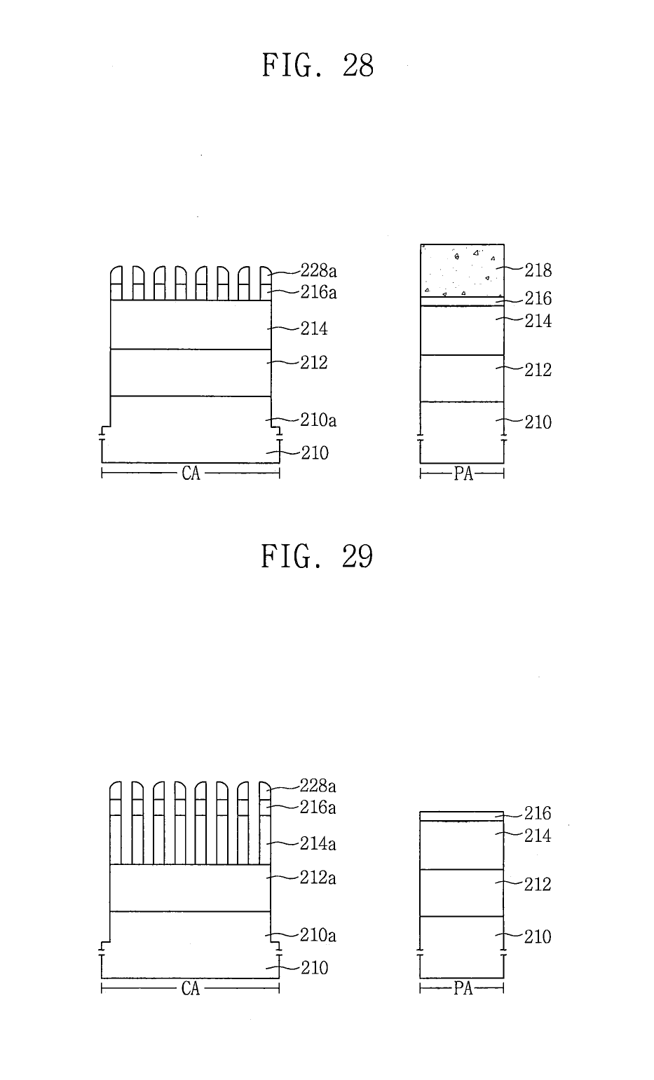

Referring to FIG. 28, the method may include forming third hard mask patterns 216a in the cell area CA.

The forming of the third hard mask patterns 216a may include selectively etching the third hard mask material layer 216 using the second spacers 228a as etch masks. While the third hard mask material layer 216 is removed, upper parts of the second spacers 228a may be etched and thus the heights of the second spacers 228a may be significantly reduced. The second hard mask material layer 214 may be exposed by the third hard mask patterns 216a.

In the peripheral area PA, the fifth hard mask material layer 220 may be removed while the third hard mask material layer 216 of the cell area CA is etched. Thus, the fourth hard mask material layer 218 may be exposed.

Referring to FIG. 29, the method may include forming second hard mask patterns 214a in the cell area CA.

The forming of the second hard mask patterns 214a may include selectively etching the second hard mask material layer 214 using the third hard mask patterns 216a as etch masks.

In the peripheral area PA, the fourth hard mask material layer 218 may be removed and the third hard mask material layer 216 may be exposed.

Then, the second spacers 228a and the third hard mask patterns 216a of the cell area CA may be removed and the third hard mask material layer 216 of the peripheral area PA may be removed.

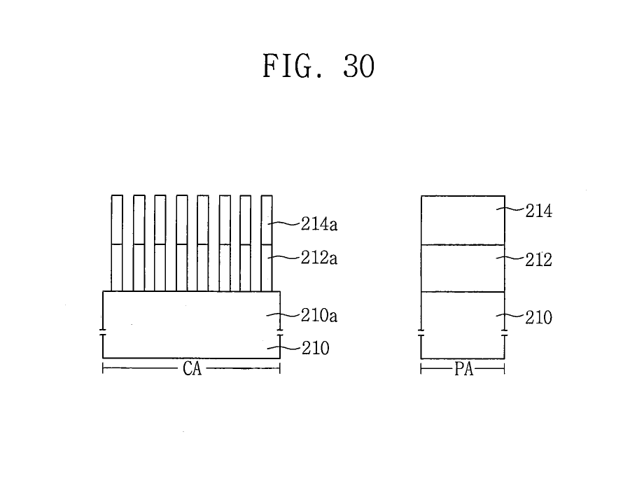

Referring to FIG. 30, the method may include forming first hard mask patterns 212a in the cell area CA.

The forming of the first hard mask patterns 212a may include selectively etching the first hard mask material layer 212 using the second hard mask patterns 214a as etch masks. In the peripheral area PA, the second hard mask material layer 214 may be exposed.

Then, the second hard mask patterns 214a of the cell area CA and the second hard mask material layer 214 of the peripheral area PA may be removed.

Hereinafter, FIGS. 31 to 36 are cross-sectional views showing trimming the first hard mask patterns 212a to shapes of the active patterns shown in FIG. 15A. Since the device is highly integrated, an example in which the trimming process is performed twice will be described. Fewer or greater number of trimming steps may be used. Referring to FIGS. 31 and 32, the method may include forming a seventh hard mask material layer 230, an eighth hard mask material layer 232, and second PR patterns 224b.

The seventh hard mask material layer 230 may fill spaces between the first hard mask patterns 212a and cover the first hard mask patterns 212a. The seventh hard mask material layer 230 and the eighth hard mask material layer 232 may be stacked across the cell area CA and the peripheral area PA. The seventh hard mask material layer 230 may include an SOH layer. The eighth hard mask material layer 232 may include silicon oxynitride (SiON) and/or a BARC layer.

The second PR patterns 224b may be formed on an upper surface of the eighth hard mask material layer 232 across the cell area CA and the peripheral area PA. In the cell area CA, the second PR patterns 224b may include a plurality of first through holes TH1. For convenience of description, the first through holes TH1 and second through holes TH2 are shown in FIG. 31 to be alternately disposed along a longitudinal direction of the first hard mask patterns 212a. However, in fact, since the second through holes TH2 are not formed in this process, the second through holes TH2 are shown with dotted lines.

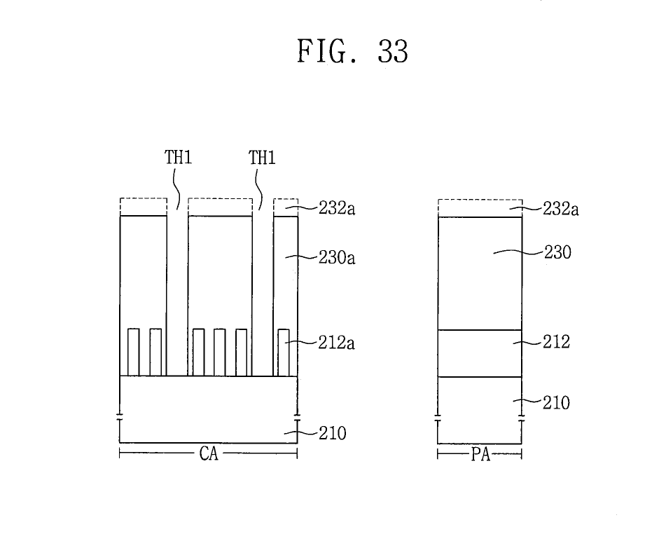

Referring to FIG. 33, the method may include forming eighth hard mask patterns 232a and seventh hard mask patterns 230a in the cell area CA, and removing the first hard mask patterns 212a corresponding to the first through holes TH1.

The forming of the eighth hard mask patterns 232a may include selectively etching the eighth hard mask material layer 232 using the second PR patterns 224b as etch masks. The forming of the seventh hard mask patterns 230a may include selectively etching the seventh hard mask material layer 230 using the eighth hard mask patterns 232a as etch masks. Some of the first hard mask patterns 212a may be partially cut by etching some of the first hard mask patterns 212a corresponding to the first through holes TH1 using the seventh hard mask patterns 230a as etch masks. Thus, some of the first hard mask patterns 212a may have island shapes and may be separated from each other. The seventh hard mask patterns 230a of the cell area CA and the seventh hard mask material layer 230 of the peripheral area PA may be removed.

Referring to FIGS. 34 and 35, the method may include stacking a ninth hard mask material layer 234 and a tenth hard mask material layer 236 across the cell area CA and the peripheral area PA, and forming a third cell PR pattern 224ca and a third peripheral PR pattern 224cb.

The ninth hard mask material layer 234 may fill the spaces between the first hard mask patterns 212a and cover the first hard mask patterns 212a. The ninth hard mask material layer 234 may include an SOH layer and the tenth hard mask material layer 236 may include silicon oxynitride (SiON) and/or a BARC layer.

In the cell area CA, the third cell PR pattern 224ca may include a plurality of second through holes TH2. Referring to FIG. 34, the second through holes TH2 may be formed at locations spaced a predetermined distance from cutting parts CP (for trimming) of the first hard mask patterns 212a. In the peripheral area PA, the third peripheral PR pattern 224cb may be formed to have an island shape. The tenth hard mask material layer 236 formed under the third peripheral PR pattern 224cb may be exposed around the third peripheral PR pattern 224cb.

Referring to FIG. 36, the method may include forming tenth cell hard mask patterns 236a and ninth cell hard mask patterns 234a in the cell area CA, and etching the first hard mask patterns 212a corresponding to the second through holes TH2. The method may include forming tenth peripheral hard mask patterns 236b, ninth peripheral hard mask patterns 234b, and first peripheral hard mask patterns 212b in the peripheral area PA.

The forming of the tenth cell hard mask patterns 236a and the tenth peripheral hard mask patterns 236b may include selectively etching the tenth hard mask material layer 236 formed under the third cell PR pattern 224ca and the third peripheral PR pattern 224cb using the third cell PR pattern 224ca and the third peripheral PR pattern 224cb as etch masks.

The forming of the ninth cell hard mask patterns 234a and the ninth peripheral hard mask patterns 234b may include selectively etching the ninth hard mask material layer 234 using the tenth cell hard mask patterns 236a and the tenth peripheral hard mask patterns 236b as etch masks.

In the cell area CA, some of the first hard mask patterns 212a may partially cut by etching some of the first hard mask patterns 212a corresponding to the second through holes TH2 using the ninth cell hard mask patterns 234a as etch masks. Thus, some of the first hard mask patterns 212a may have island shapes and may be separated from each other. Therefore, the first hard mask patterns 212a may be formed to be bar shaped, which are separated from each other, as shown in the active patterns 210a of FIG. 15A. In some embodiments of the inventive concept, a trimming process for cutting the first hard mask patterns 212a may be performed in a single process.

The forming of the first peripheral hard mask patterns 212b in the peripheral area PA may include selectively etching the first hard mask material layer 212 using the ninth peripheral hard mask patterns 234b as etch masks.

Referring to FIG. 37, the method may include forming a plurality of active patterns 210a in the cell area CA and forming a peripheral active pattern 210b in the peripheral area PA.

The forming of the cell active patterns 210a and the peripheral active pattern 210b may include etching the substrate 210 using the first hard mask patterns 212a and the first peripheral hard mask patterns 212b being bar shaped as etch masks. First trenches T1 may be formed between the cell active patterns 210a in the cell area CA by etching the substrate 210, and second trenches T2 may be formed in the peripheral area PA. Side walls of the first trenches T1 may be side walls of the cell active patterns 210a and side walls of the second trenches T2 may be side walls of the peripheral active patterns 210b.

Through the above-described etching process, the cell active patterns 210a and the peripheral active pattern 210b may be formed such as those described with reference to FIGS. 15a and 15b.

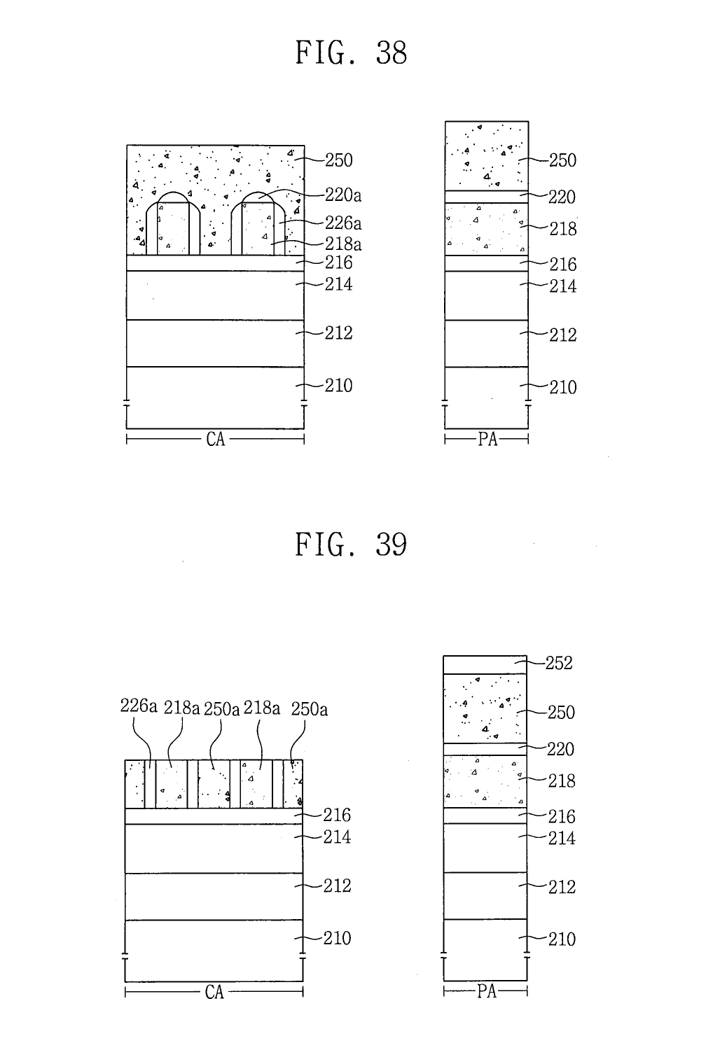

Hereinafter, FIGS. 38 to 40 are cross-sectional views showing a method of fabricating a semiconductor device according to embodiments of the inventive concept. FIGS. 38 to 40 are cross-sectional views corresponding to lines I-I′ and II-II′ of FIG. 15A.

Processes which are performed before the following processes may be the same as those described with reference to FIGS. 17 to 21.

Referring to FIG. 38, the method of fabricating the semiconductor device in accordance with embodiments of the inventive concept may include forming an auxiliary hard mask material layer 250 in the cell area CA and the peripheral area PA.

In the cell area CA, the auxiliary hard mask material layer 250 may fill spaces between the first spacers 226a and cover the fifth hard mask patterns 220a. In the peripheral area PA, the auxiliary hard mask material layer 250 may cover the fifth hard mask material layer 220. The auxiliary hard mask material layer 250 may include an SOH layer.

Referring to FIG. 39, the method may include forming a peripheral auxiliary PR pattern 252 in the peripheral area PA, planarizing an upper end of the first spacers 226a of the cell area CA, and forming auxiliary hard mask patterns 250a between the first spacers 226a.

The planarizing of the upper end of the first spacers 226a and the forming of the auxiliary hard mask patterns 250a may include a planarization process. The planarization process may include an etch-back process. Through the planarization process, surfaces of the first spacers 226a, the auxiliary hard mask patterns 250a, and the fourth hard mask patterns 218a may be planarized, and a height of the peripheral PR pattern 252 may be reduced.

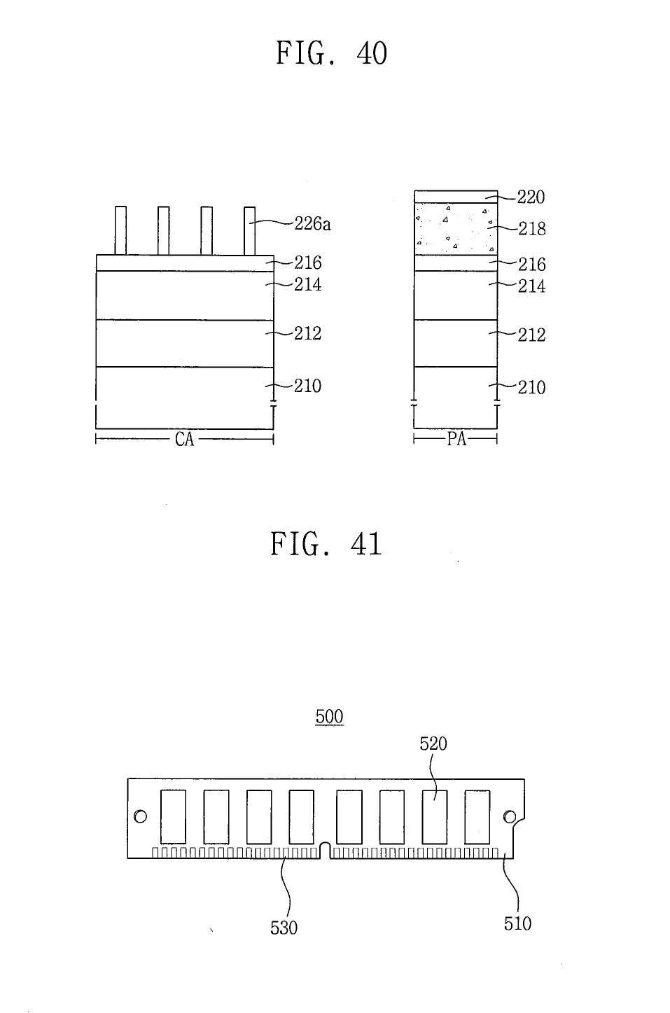

Referring to FIG. 40, the method may include removing the fourth hard mask patterns 218a, which fill between the first spacers 226a, and the auxiliary hard mask patterns 250a, and leaving the first spacers 226a spaced apart from each other on the upper surface of the third hard mask material layer 216. The method may further include removing the peripheral PR pattern 252 and the auxiliary hard mask material layer 250 in the peripheral area PA. In the peripheral area PA, the fifth hard mask material layer 220 may be exposed.

Then, the method may include forming the cell active patterns 210a and the peripheral active pattern 210b shown in FIGS. 15A and 15B by performing the processes described with reference to FIGS. 25 to 37.

FIG. 41 illustrates a semiconductor module in accordance with embodiments of the inventive concept. Referring to FIG. 41, the semiconductor module 500 in accordance with embodiments of the inventive concept may include memory chips 520 mounted on a module substrate 510. The memory chips 520 may include the semiconductor devices according to embodiments of the inventive concept. Input/output terminals 530 may be disposed on at least one side of the module substrate 510.

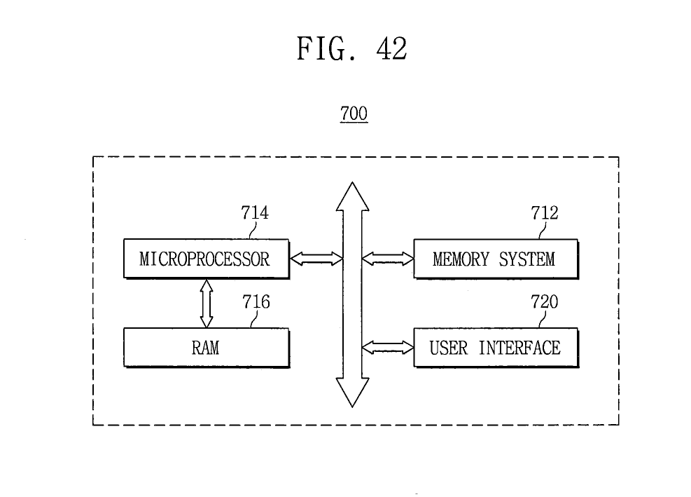

FIG. 42 is a block diagram showing an electronic system in accordance with embodiments of the inventive concept.

Referring to FIG. 42, the electronic system 700 may include the semiconductor devices fabricated according to embodiments of the inventive concept.

The electronic system 700 may be applied to a mobile device or a computer. For example, the electronic system 700 may include a memory system 712, a microprocessor 714, a RAM 716, and a user interface 720 which performs data communication using a bus. The microprocessor 714 may program and control the electronic system 700. The RAM 716 may be used as an operational memory of the microprocessor 714. For example, the microprocessor 714 or the RAM 716 may include one of the semiconductor devices according to the embodiments of the inventive concept. The microprocessor 714, the RAM 716, and/or other components may be assembled within a single package. The user interface 720 may be used to input data to the electronic system 700, or output data from the electronic system 700. The memory system 712 may store operational codes of the microprocessor 714, data processed by the microprocessor 714, or data received from the outside. The memory system 712 may include a controller and a memory.

According to the methods of fabricating the semiconductor devices in accordance with embodiments of the inventive concept, a QPT process is simplified, and thus product yields of the semiconductor devices can be improved and manufacturing costs can be reduced.

A smoothing process is performed on rounded ends of the first spacers, and thus a distribution characteristic of the second spacers which are self-aligned on sidewalls of the first spacers can be improved. In some embodiments, smoothing is performed by reducing the height of one side of the spacer relative to the other so that the entire upper surface of the spacer is more planar.

The distribution characteristic of the second spacers is improved, and thus errors of widths and distances of fine patterns which are formed using the second spacers as etch masks can be reduced and process yields can be improved. In other words, in some embodiments, smoothing the upper surface of the first spacers can make the widths and spacing between each of the second spacers more uniform.

Although embodiments have been described with reference to the accompanying drawings, those skilled in the art will readily appreciate that many modifications are possible in embodiments without departing from the scope of the inventive concept and without changing essential features. Therefore, the above-described embodiments should be considered in a descriptive sense only and not for purposes of limitation.

What is claimed:

1. A method of fabricating a semiconductor device, comprising:
providing an etching target layer;
forming a hard mask pattern on the etching target layer;
forming first spacers on opposing sidewalls of the hard mask pattern;
removing the hard mask pattern and maintaining the first spacers on the etching target layer;
increasing planarization of top surfaces of the first spacers; and
forming second spacers on opposing sidewalls of the first spacers.

2. The method of claim 1, wherein forming the hard mask pattern comprises:
forming a hard mask material layer on the etching target layer and forming a photoresist pattern on an upper surface of the hard mask material layer; and
selectively etching the hard mask material layer using the photoresist pattern as an etch mask.

3. The method of claim 1, wherein the etching target layer comprises polysilicon, a metal, or a semiconductor substrate.

4. The method of claim 1, wherein:
the hard mask pattern comprises a spin on hardmask (SOH);
each of the first spacers comprises polysilicon; and
each of the second spacers comprises silicon oxide.

5. The method of claim 4, further comprising:
forming a silicon oxynitride layer or a silicon nitride layer between the hard mask pattern and the etching target layer.

6. The method of claim 1, wherein forming the first spacers comprises:
forming a first spacer material layer on the etching target layer to conformally cover the opposing sidewalls of the hard mask pattern; and
anisotropically etching the first spacer material layer so as to expose an upper surface of the hard mask pattern and to separate the first spacer material layer on the opposing sidewalls of the hard mask pattern into separate spacers.

7. The method of claim 1, wherein forming the second spacers comprises:
forming a second spacer material layer on the etching target layer to conformally cover the opposing sidewalls of the first spacers; and
anisotropically etching the second spacer material layer to expose the top surfaces of the first spacers.

8. The method of claim 1, wherein increasing the planarization comprises removing rounded upper ends of the top surfaces of the first spacers using an etching process.

9. The method of claim 8, wherein the etching process comprises a plasma etching process.

10. The method of claim 1, further comprising:
selectively removing the etching target layer using the second spacers as etch masks and to provide target patterns.

11. A method of fabricating a semiconductor device, comprising:
providing an etching target layer;
forming a first hard mask pattern and a second hard mask pattern sequentially stacked on the etching target layer;
forming first spacers on sidewalls of the first and second hard mask patterns;
forming an auxiliary hard mask material layer to fill a space between the first spacers and to cover the second hard mask pattern;
removing an upper part of the auxiliary hard mask material layer and the second hard mask pattern and forming an auxiliary hard mask pattern between the first spacers;
planarizing upper surfaces of the first spacers, the first hard mask pattern, and the auxiliary hard mask pattern;
removing the first and auxiliary hard mask patterns; and
forming second spacers on side surfaces of the first spacers.

12. The method of claim 11, wherein each of the first hard mask pattern and the auxiliary hard mask pattern comprises an SOH.

13. The method of claim 11, wherein planarizing the first hard mask pattern, the first spacers, and the auxiliary hard mask patterns comprises performing an etch-back process.

14. The method of claim 11, wherein the first spacers comprise polysilicon, and the second spacers comprise silicon oxide.

15. The method of claim 11, further comprising:
forming a silicon oxynitride layer between the first hard mask pattern and the etching target layer.

16. A method of forming a semiconductor pattern, comprising:
providing an etching target layer;
forming a hard mask pattern on the etching target layer using photolithography;
forming first spacers on opposing sidewalls of the hard mask pattern;
removing the hard mask pattern from between the first spacers to provide a first double patterning pattern self-aligned to the hard mask pattern; and
increasing planarization of top surfaces of the first double patterning pattern to provide a smoothed first double patterning pattern.

17. The method of claim 16 further comprising:
forming second spacers on opposing sidewalls of the smoothed first double patterning pattern to provide a first quadruple patterning pattern self-aligned to the smoothed first double patterning pattern.

18. The method of claim 17 further comprising:
increasing planarization of top surfaces of the first quadruple patterning pattern to provide a smoothed first quadruple patterning pattern.

19. The method of claim 16 wherein removing the hard mask pattern and increasing planarization of top surfaces of the first double patterning pattern are performed separately.

20. The method of claim 16, wherein increasing the planarization comprises removing rounded upper ends of the top surfaces of the first double patterning pattern using an etching process.
